(19) United States
(12) Patent Application Publication
(10) Pub. No.: US 2009/0294816 A1
(43) Pub. Date: Dec. 3, 2009

(54) CMOS image sensor and driving method of the same

(75) Inventors: Jong-Eun Park, Seongnam-si (KR); Jung-Chak Ahn, Yongin-si (KR); Yong-Jei Lee, Seongnam-si (KR); Dong-Yoon Jang, Hwaseong-si (KR)

Correspondence Address: HARNESS, DICKEY & PIERCE, P.L.C., P.O. BOX 8910, RESTON, VA, 20195, US

(73) Assignee: SAMSUNG ELECTRONICS CO., LTD.

(21) Appl. No.: 12/453,532

(22) Filed: May 14, 2009

(30) Foreign Application Priority Data
Jun. 2, 2008 (KR) 10-2008-0051641

(51) Int. Cl. H01L 31/112

(52) U.S. Cl. 257/292; 257/E31.079

(57) ABSTRACT

Provided are a CMOS image sensor and a driving method thereof. The CMOS image sensor may include a photodetector disposed in a semiconductor substrate to accumulate photocharges, a charge transfer element configured to control transfer of the photocharges accumulated in the photodetector, a detecting element configured to detect the photocharges transferred by the charge transfer element, and a well driving contact configured to increase a potential difference between the photodetector and the detecting element while the photocharges are transferred.

### CROSS-REFERENCE TO RELATED APPLICATION

This U.S non-provisional patent application claims priority under 35 U.S.C §119 to Korean Patent Application No. 10-2008-0051641, filed on Jun. 2, 2008, in the Korean Intellectual Property Office (KIPO), the entire contents of which are incorporated herein by reference.

### BACKGROUND

1. Technical Field

Example embodiments relates to a CMOS image sensor and a driving method of the same. More specifically, example embodiments are directed to a CMOS image sensor capable of improving charge transfer efficiency and a driving method of the same.

2. Description of Related Art

An image sensor is a semiconductor device that converts optical images into electrical signals. Image sensors may be typically classified into charge coupled device (CCD) image sensors and complementary metal oxide semiconductor (CMOS) image sensors.

A CCD is a device in which individual MOS capacitors may be disposed very close to each other and charge carriers may be stored in and transferred by the capacitors. A CMOS image sensor is a device that may employ a switching mode of forming MOS transistors for pixels using CMOS technology to detect outputs using the MOS transistors.

A typical CMOS image sensor may be comprised of an active pixel sensor (APS) array region where light is sensed to generate an electrical signal and a logic region (peripheral circuit region) where the generated electrical signal is processed. Each unit pixel of the APS array region may include a transfer gate electrode, photodiodes disposed at opposite sides of the transfer gate electrode, respectively, and a floating diffusion area.

An operation of an APS will now described in brief. If light impinges on a spot within a photodiode, an electron-hole pair (EHP) may be generated and accumulated in the photodiode. The accumulated EHP may be carried to a diffusion area to change a potential at a floating diffusion area.

### SUMMARY

Example embodiments provide a CMOS image sensor. According to example embodiments, the CMOS image sensor may include: a photodetector disposed in a semiconductor substrate to accumulate photocharges; a charge transfer element configured to control transfer of the photocharges accumulated in the photodetector; a detecting element configured to detect the photocharges transferred by the charge transfer element; and a well driving contact configured to increase a potential difference between the photodetector and the detecting element while the photocharges are transferred.

According to example embodiments, the CMOS image sensor may include: a semiconductor substrate including a plurality of pixel regions; photodetectors disposed at the semiconductor substrate of the pixel regions to accumulate photocharges, respectively; a charge transfer element configured to control transfer of the photocharges accumulated in the photodetector; a detecting element configured to detect the photocharges transferred by the charge transfer element; and a well driving contact configured to increase a potential difference between the photodetector and the detecting element while the photocharges are transferred, wherein adjacent pixel regions share the well driving contact.

Example embodiments provide a driving method of a CMOS image sensor. According to example embodiments, the driving method may include: accumulating photocharges in a photodetector; receiving a charge transfer signal to transfer the photocharges to a detecting element; and providing a well driving signals, while the photocharges are transferred, to increase a potential difference between the photodetector and the detecting element.

### BRIEF DESCRIPTION OF THE DRAWINGS

The above and other features and advantages of example embodiments will become more apparent by describing in detail example embodiments with reference to the attached drawings. The accompanying drawings are intended to depict example embodiments and should not be interpreted to limit the intended scope of the claims. The accompanying drawings are not to be considered as drawn to scale unless explicitly noted.

FIG. 1 is a block diagram of a CMOS image sensor according to example embodiments.

FIG. 2 is a circuit diagram of an active pixel sensor (APS) array of a CMOS image sensor according to example embodiments.

FIG. 3 is a top plan view of an active pixel sensor (APS) array according to example embodiments.

FIG. 4 is a cross-sectional view taken along the line IV-IV′ of FIG. 3, which illustrates an active pixel sensor (APS) according to example embodiments.

FIG. 5 is a circuit diagram illustrating a modified version of the active pixel sensor (APS) of the CMOS image sensor according to the embodiment of example embodiments.

FIG. 6 is a top plan view illustrating a modified version of the active pixel sensor (APS) according to example embodiments.

FIG. 7 is a cross-sectional view taken along the line VII-VII′ of FIG. 6, which illustrates a modified version of the active pixel sensor (APS) array according to example embodiments.

FIG. 8 is a top plan view of an active pixel sensor (APS) array according to example embodiments.

FIG. 9 is a cross-sectional view taken along the line IX-IX′ of FIG. 8, which illustrates an active pixel sensor (APS) according to example embodiments.

FIG. 10A is a top plan view of a unit pixel, which illustrates the operation of a CMOS image sensor according to example embodiments.

FIG. 10B is a timing diagram of the CMOS image sensor according to the example embodiments.

FIG. 10C is a potential diagram of the CMOS image sensor according to example embodiments.

### DETAILED DESCRIPTION OF THE EMBODIMENTS

Detailed example embodiments are disclosed herein. However, specific structural and functional details disclosed herein are merely representative for purposes of describing example embodiments. Example embodiments may, however, be embodied in many alternate forms and should not be construed as limited to only the embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but to the contrary, example embodiments are to cover all modifications, equivalents, and alternatives falling within the scope of example embodiments. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

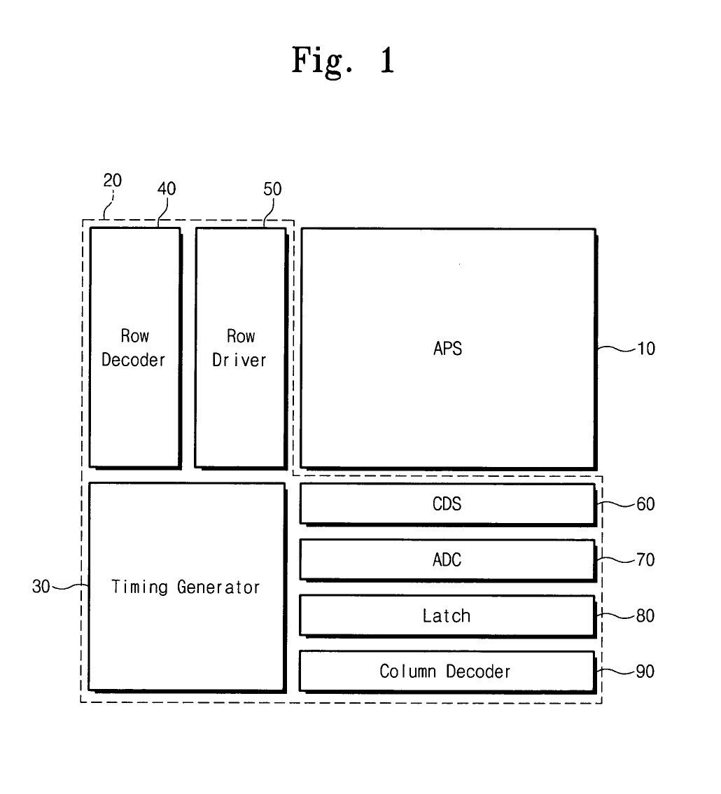

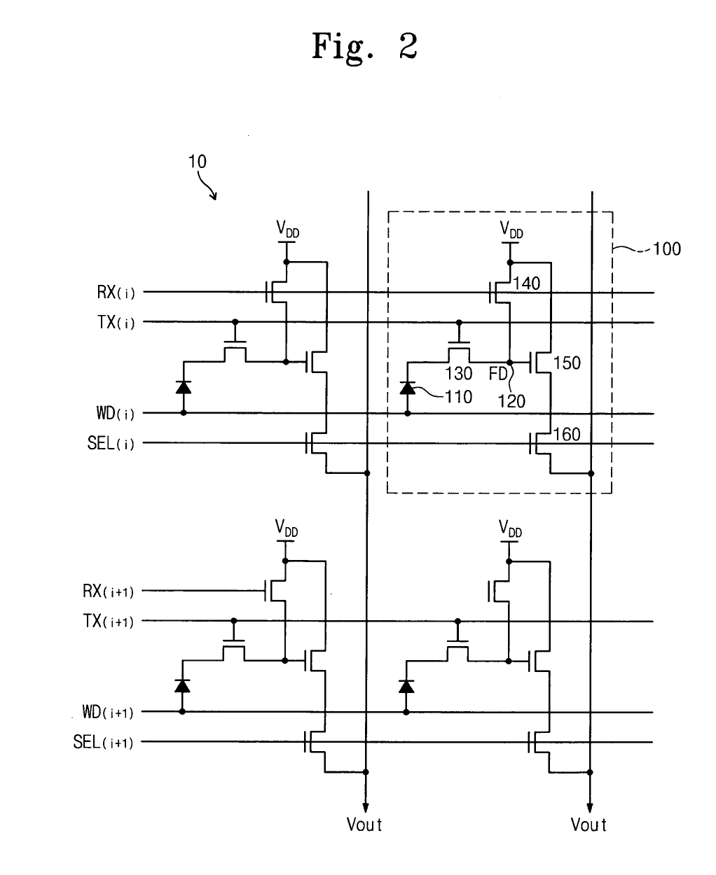

The configuration of a CMOS image sensor according to example embodiments will now be described below in detail with reference to FIGS. 1 and 2.

FIG. 1 is a block diagram of a CMOS image sensor according to example embodiments. The CMOS image sensor may include an active pixel sensor (APS) array region 10 where pixels, each of which may include a photodetector, are arranged 2-dimensionally, and a logic region 20 provided to control the APS array region 10.

The APS array region 10 may be provided to convert an optical signal to an electrical signal. The APS array region 10 may be driven by receiving a plurality of driving signals, for example as a pixel selection signal SEL(i), a reset signal RX(i), and a charge transfer signal TX(i) from a row driver 50. The converted electrical signal may be transmitted to a correlated double sampler (CDS) 60 through a vertical signal line.

The logic region 20 may include a timing generator 30, a row decoder 40, a row driver 50, the CDS 60, an analog-to-digital converter (ADC) 70, a latch 80, and/or a column decoder 90.

The timing generator 30 may transmit a timing signal and a control signal to the row decoder 40 and the column decoder 90. The row driver 50 may transmit a plurality of driving signals to the APS array region 10. The driving signals may be provided to drive a plurality of unit pixels according to the result decoded at the row decoder 40. If unit pixels are arranged in a matrix of rows and columns, a driving signal may be transmitted to the respective rows.

The CDS 60 may receive an electrical signal generated at the APS array region 10 through a vertical signal line, and the CDS 60 may hold and sample the received electrical signal. According to example embodiments, the CDS 60 may double-sample a specific noise level and a signal level based on the generated electrical signal to output a difference level that is equivalent to a difference between the noise level and the signal level. The ADC 70 may convert an analog signal corresponding to the difference level to a digital signal and output the converted digital signal. The latch 80 may latch the digital signal. According to the result decoded at the column decoder 90, latched signals may be sequentially output to an image signal processor (not shown).

FIG. 2 is a circuit diagram of an active pixel sensor (APS) array of a CMOS image sensor according to example embodiments.

Referring to FIG. 2, an APS array region 10 with an image sensor provided to convert an optical signal to an electrical signal may include a plurality of unit pixels 100 arranged in a matrix. Although FIG. 2 shows the case where a unit pixel 100 includes four transistors, according to example embodiments, the unit pixel 100 may also include, for example, three transistors, five transistors or a photogate which is similar to the four transistors.

Each unit cell 100 including four NMOS transistors may be comprised of a photodetector 110 and a read element. The photodetector 110 may receive light to generate and accumulate photocharges, and the read element may read an optical signal impinging on the photodetector 110. The read element may include a reset element 140, an amplifier 150, and a selector 160.

More specifically, the photodetector 110 may generate and accumulate charges corresponding to incident light and may be one selected from the group consisting of, for example, a photodiode, a phototransistor, a photogate, a pinned photodiode (PPD), and combinations thereof. The photodetector 110 may be coupled to a charge transfer element 130 which may be configured to transmit the accumulated charges to a detecting element 120.

The detecting element 120 may mainly employ a floating diffusion region FD and receive the accumulated charges from a photoelectric converter 110. The detecting element 120 may be configured to accumulatively store charges and may be electrically connected to the amplifier 150 to control the same.

The charge transfer element 130 may transfer charges to the detecting element 120 from the photodetector 110. The charge transfer element 130 may generally include one transistor and may be controlled by a charge transfer signal TX(i).

The reset element 140 may be configured to periodically reset the detecting element 120 and may be driven by a bias that a reset signal Rx(i) provides. A source of the reset element 140 may be connected to the detecting element 120, and a drain thereof may be connected to a power supply voltage V_{DD}. Therefore, if the reset element 140 is turned on by the bias that the reset signal Rx(i) provides, the power supply voltage V_{DD} connected to the drain of the reset element 140 may be transferred to the detecting element 120. As a result, the detecting element 120 may be reset when the reset element 140 is turned on.

The amplifier 150 may function as a source follower buffer amplifier in combination with an external constant current source (not shown). The amplifier 150 may be configured to amplify an electrical potential change of the detecting element 120 and output the amplified electrical potential change to an output line Vout.

The selector 160 may be configured to select a unit pixel to be read by row unit and driven by a bias that a row selection line SEL(i) provides. If the selector 160 is turned on, a power supply voltage connected to a drain of the amplifier 150 may be transferred to a drain of the selector 160.

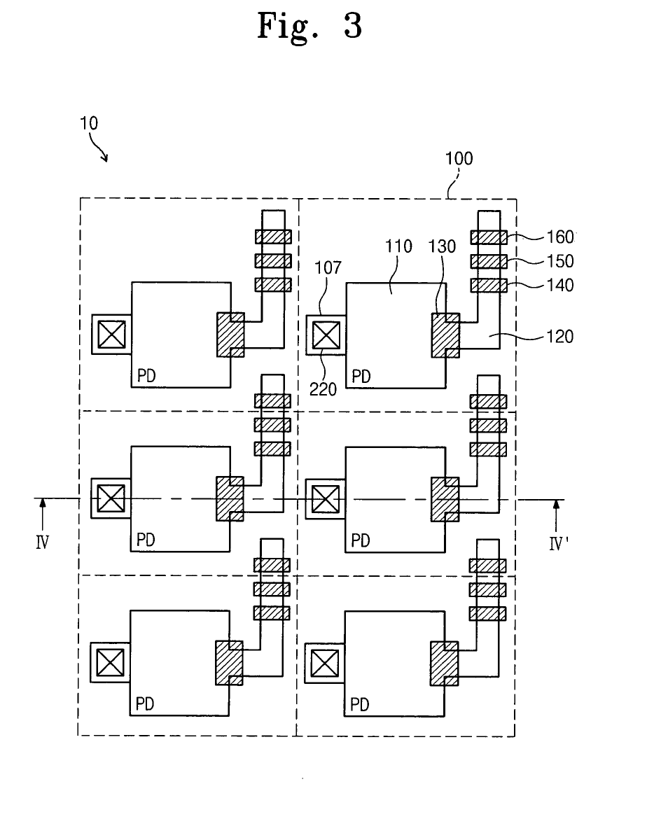

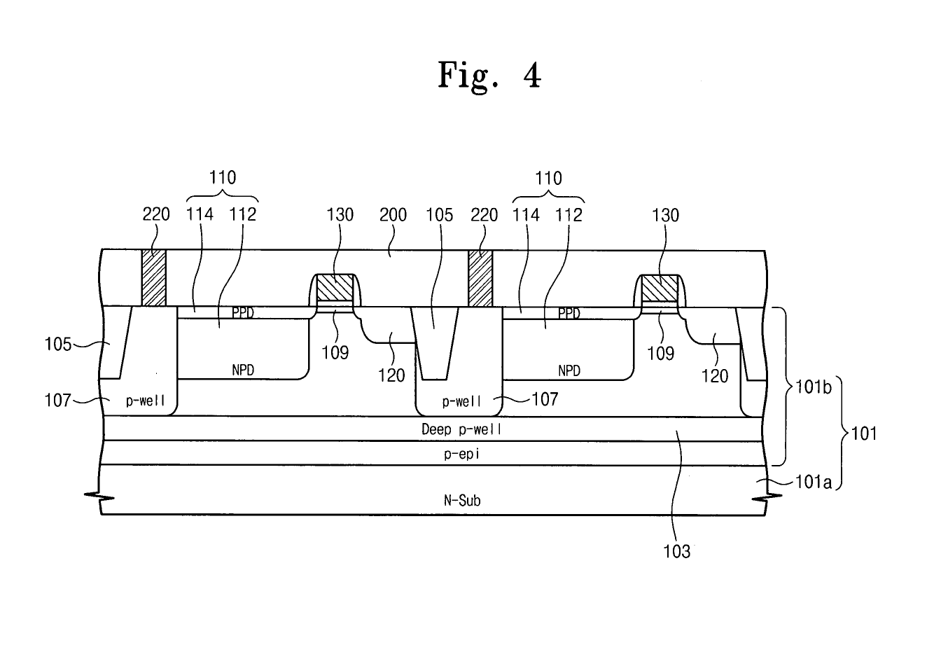

The driving signal lines TX(i), RX(i), and SEL(i) of the charge transfer element 130, the reset element 140, and the selector 160 may extend in a row (horizontal) direction to simultaneously drive unit pixels included in one row. A well driving signal WD(i) may be supplied to the respective unit cells to lower a potential at the periphery of the photodetector 110 when charges are transferred. According to the charge transfer signal TX(i), the well driving signal WD(i) may be negatively boosted to apply a negative voltage to an isolation well 107, which is discussed above with reference to FIGS. 3 and 4. The well driving signal WD(i) may be supplied during activation of the charge transfer signal TX(i) and extends in a row (horizontal) direction to be simultaneously supplied to unit pixels included in one row.

FIG. 3 is a top plan view of an active pixel sensor (APS) array according to example embodiments. The APS array 10, which is discussed above with reference to FIG. 1, may divide a substrate 101 into tetragonal unit pixels 100 because the unit cells 100 are arranged in a matrix. A photodetector 110 may be included in the respective unit cells 100. A detecting element 120, a charge transfer element 130, a reset element 140, an amplifier 150, and a selector 160 may be disposed in the respective pixels 100 at the periphery of the photodetector 110. According to example embodiments, when there is a short distance between an amplifier 150 and a selector 160, they may be called a MOS transistor.

In the respective unit cell, an isolation well 107 for well driving may be formed adjacent to the photodetector 110. The isolation well 107 may be formed throughout the periphery of the photodetector 110 or within a predetermined region. In case the isolation well 107 is formed within a predetermined region, the isolation well 107 may be disposed opposite to the detecting element 120 in consideration of a potential profile. According to example embodiments, the isolation well 107 may be disposed adjacent to the photodetector 110 and spaced apart from the detecting element 120. The isolation well 107 for well driving will be described later in detail.

FIG. 4 is a cross-sectional view taken along the line IV-IV′ of FIG. 3, which illustrates a CMOS image sensor according to example embodiments. The CMOS image sensor may employ a substrate 101 including a bulk substrate 101a on which an epitaxial layer 101b is formed.

A device isolation layer 105 may be formed in the substrate 101 to define an active region and a field region. The device isolation layer 105 may be made of field oxide (FOX) using local oxidation of silicon (LOCOS). A photodetector 110 may be disposed at the active region defined by the device isolation layer 105.

In the substrate 101, a well region may be formed at the periphery of the photodetector 110 and below the device isolation layer 105. According to example embodiments, the well region may include an epitaxial layer 101b, a deep well 103 and/or an isolation well 107 which may be formed in the substrate 101. The well region and the photodetector 110 may have opposite conductivity types. For example, if the photodetector 110 is N-type, the well region may be P-type and vice versa.

More specifically, a deep well 103 may be formed in the epitaxial layer 101b. The deep well 103 may be an impurity region spaced apart from a surface of the substrate 101. The deep well 103 may cause a potential barrier to be formed for preventing charges generated at a deep spot of the bulk substrate 101a from flowing to the photodetector 110 and may increase charge-hole recombination. Thus, the deep well 103 may function as a crosstalk barrier to suppress inter-pixel crosstalk resulting from random drift of the charges.

The deep well 103 may have a maximum concentration at a depth between 3 and 12 micrometers from the surface of the substrate 101 and may be formed to a thickness between 1 and 5 micrometers. Note that the depth between 3 and 12 micrometers is substantially equal to adsorption depth of infrared or near infrared light in silicon. The smaller the depth of the deep well 103 is with respect to the surface of the substrate 101, the greater the efficiency of a diffusion barrier may be. Accordingly, crosstalk may be reduced or a region of the photodetector 110 may also become shallow to decrease sensitivity to incident light having a long wavelength, for example, a red wavelength, where a photoelectric conversion rate is relatively high at a depth spot. As a result, formation position of the deep well 103 may vary with the wavelength range of the incident light.

An isolation well 107 may be formed below the device isolation layer 105. The isolation well 107 may extend from the surface of the substrate 101 to the deep well 103 to isolate a plurality of photodetectors 110 formed in an APS array region from one another. According to example embodiments, the isolation well 107 may extend to the deep well 103 to prevent crosstalk between unit pixels.

The isolation well 107 may be formed throughout the periphery of the photodetector 110 or at each defined region at the periphery of the photodetector 110. A top surface of an isolation well 107, which may be adjacent to the photodetector 110 and spaced apart from the detecting element 120, may be partially or entirely exposed to connect the isolation well 107 to an overlying well driving contact 220.

There may be majority charge carriers, for example, holes, in the well region. When the charges are transferred, the majority charge carriers may be ejected through the well driving contact 220.

More specifically, while the charges are transferred, a predetermined negative voltage may be applied to the isolation well 107 to decrease a potential at the periphery of the photodetector 110. Thus, a difference between a potential at the photodetector 110 and a potential at the isolation well 107 may increase to make a gradient of the potential larger. With the increase of difference between the potentials at the photodetector 110 and the detecting element 120, charge transfer efficiency may be improved. A negative voltage, which may be between −1.2 volts and 0 volts, may be applied to the well driving contact 220 according to a well driving signal while the charges are transferred. Specifically, excess holes generated at the deep well 103 and the isolation well 107 may be attracted to the periphery of the well driving contact 220. For this reason, potential of a region adjacent to the photodetector 110 may be reduced to improve transfer efficiency of photocharges.

A plurality of gate electrodes may be disposed on the substrate 101 where an active region is defined by the device isolation layer 105 and the isolation well 107. According to example embodiments, a transfer gate corresponding to a charge transfer element 130, a reset gate of the reset element 140, an amplifier gate of the amplifier 150, and a selection gate of the selector 160 may be disposed on the substrate 101 of a unit pixel.

In case the charge transfer element 130 is an NMOS transistor, a P-type impurity region 109 may be formed below the charge transfer element 130 to control a threshold voltage. When photocharges are transferred, the P-type impurity region 109 may decrease off current to suppress generation of dark current.

Now, the configuration of the above-mentioned photodetector 110 will be described. According to example embodiments, the photodetector 110 may be a pinned photodiode. However, according to example embodiments, the photodetector 110 may also be substituted with other elements, for example, a photogate, a phototransistor, etc, capable of accumulating charges, for example, photoelectrons, according to incident light.

More specifically, a pinned photodiode 110 may include an N-type impurity region 112 and a P-type impurity region 114 which may be formed by performing ion implantation twice. The N-type impurity region 112 may be deeply formed in a P-type epitaxial layer 101b, and the P-type impurity region 114 may be shallowly formed on a surface of the N-type impurity region 112. As a result, the pinned photodiode 110 may have a PNP junction including the P-type epitaxial layer 101b, the N-type impurity region 112, and the P-type impurity region 114 which are stacked in the order named.

The N-type impurity region 112 may absorb incident light to accumulate photocharges, and the P-type impurity region 114 may decrease the number of thermally generated electron-hole pairs (EHPs) to prevent generation of dark current. Dark current may be generated by surface damage of a semiconductor substrate 101 including silicon dangling bonds and etching stress. Thus, holes of the thermally generated EHPs may be diffused to a grounded substrate 101 through the P-type photodiode 114 and electrons of the thermally generated EHPs may be recombined with the holes and annihilated during diffusion of the P-type photodiode 114.

A floating diffusion region formed by introducing N-type impurities may be disposed in the substrate 101 spaced apart from the pinned photodiode 110, as a detecting element 120. The detecting element 120 may receive photocharges accumulated at the pinned photodiode 110 through a charge transfer element 130. The floating diffusion region may include a lightly doped region and a heavily doped region. According to example embodiments, the floating diffusion region may have a lightly doped drain (LDD) structure or a double doped drain (DDD) structure.

Likewise if a photodetector is a pinned photodiode, an isolation well 107 may be disposed adjacent to an N-type impurity region 112 and a P-type impurity region 114. The isolation wells 107 may be doped with impurities of an opposite conductivity type with respect to that of the adjacent N-type impurity region 112. The charge transfer element 130 may be disposed on the substrate between the pinned photodiode 110 and the detecting element 120 which may be spaced apart from each other, thus controlling the transfer of photocharges to the detecting element 120.

On the substrate 101 where a photodetector 110, a detecting element 120, a charge transfer element 130, and the read elements discussed above with reference to FIG. 3 including reset element 140, amplifier 150, and selector 160, of each unit pixel may be formed, an interlayer dielectric 200 may be disposed to cover the above elements. A well driving contact 220 may be formed in the interlayer dielectric 200 to be electrically connected to an isolation well 107. A well driving contact 220 may be connected to an interconnection (not shown) to which a predetermined voltage is applied in response to a well driving signal. A heavily doped impurity region (not shown) may be formed at a region where an isolation well 107 and the well driving contact 220 are in contact with each other to lower contact resistance.

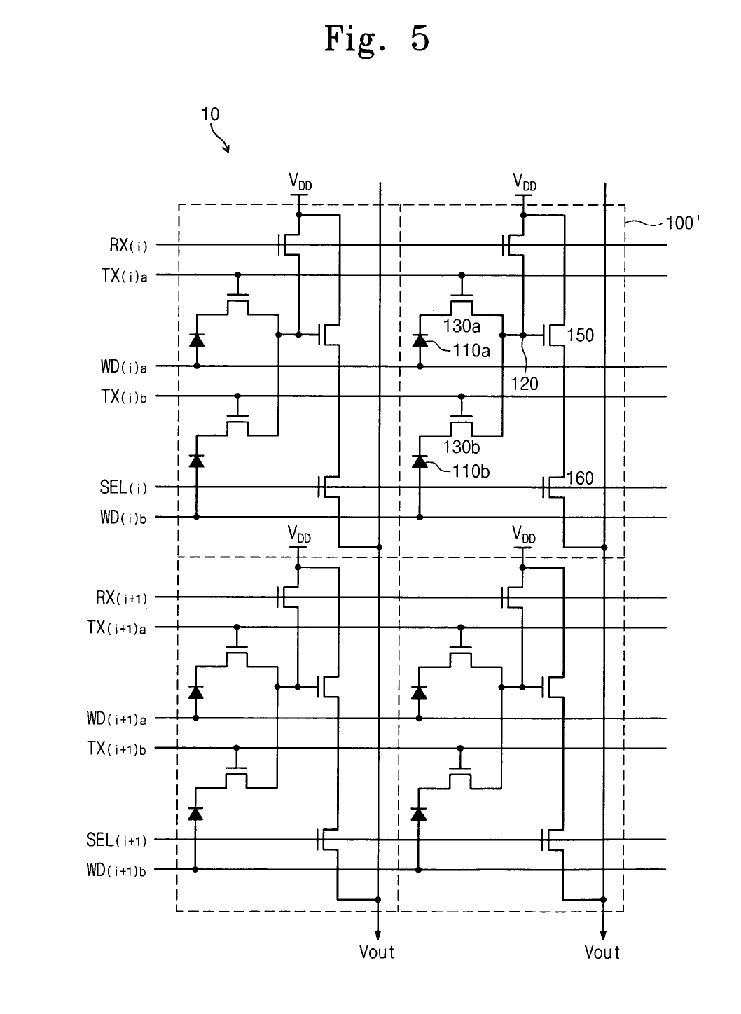

A modified version of the CMOS image sensor according to example embodiments will now be described below in detail with reference to FIGS. 5 through 7.

FIG. 5 is a circuit diagram illustrating a modified active pixel sensor (APS) array of the CMOS image sensor according to example embodiments. An APS array region may include 2-shared pixels 100′ arranged in a matrix. Each of the 2-shared pixels 100′ may include two photodetectors 110a and 110b which may share read elements 140, 150, and 160. According to example embodiments, the two photodetectors 110a and 110b may share a reset element 140, an amplifier 150 and/or a selector 160.

Specifically, each of the 2-shared pixels 100′ may include two photodiodes 110a and 110b, which may absorb incident light to accumulate charges corresponding to light intensity. Each of the photodiodes 110a and 110b may be substituted with any element capable of accumulating charges corresponding to light intensity. According to example embodiments, each of the photodiodes 110a and 110b may be substituted with, for example, a phototransistor, a photogate, a pinned photodiode or a combination thereof. The photodiodes 110a and 110b may be connected to charge transfer elements 130a and 130b, respectively. Charges transferred through the charge transfer elements 130a and 130b may be accumulatively stored in a detecting element 120 and may change a potential of the detecting element 120.

The reset element 140 may be configured to periodically reset the detecting element 120. The reset element 140 may include one MOS transistor driven by a predetermined bias that a reset line RX(i) provides. When the reset element 140 is turned on by the bias that the reset line RX(i) provides, a predetermined electrical potential, for example, a power supply voltage V_{DD}, electrically connected to a drain of the reset element 140 may be applied to the detecting element 120. The amplifier 150 may amplify change of the electrical potential of the detecting element 120 receiving the charges accumulated at the respective photodiodes 110a and 110b and output the amplified change of the electrical potential to an output line Vout. The selector 160 may be configured to select a 2-shared pixel 100′ read by row unit. The selector 160 may include one MOS transistor driven by a bias that a row selection line SEL(i) provides. Thus, when the selector 160 is turned on by the bias that the row selection line SEL(i) provides, a predetermined potential, for example, a power supply voltage V_{DD}, electrically connected to a drain of the amplifier 150 may be applied to a drain region of the selector 160.

A transfer line TX(i)a applying a bias to the charge transfer elements 130a and 130b, a set line RX(i) applying a bias to the reset element 140, and a row selection line SEL(i) applying a bias to the selector 160 may extend in a row direction to be substantially parallel with one another. Well driving signals WD(i)a and WD(i)b connected to the photodetectors 110a and 110b may extend in the row direction to be parallel with each other. While a charge transfer element is turned on, the well driving signals WD(i)a and WD(i)b may provide a negative voltage to an isolation well 107.

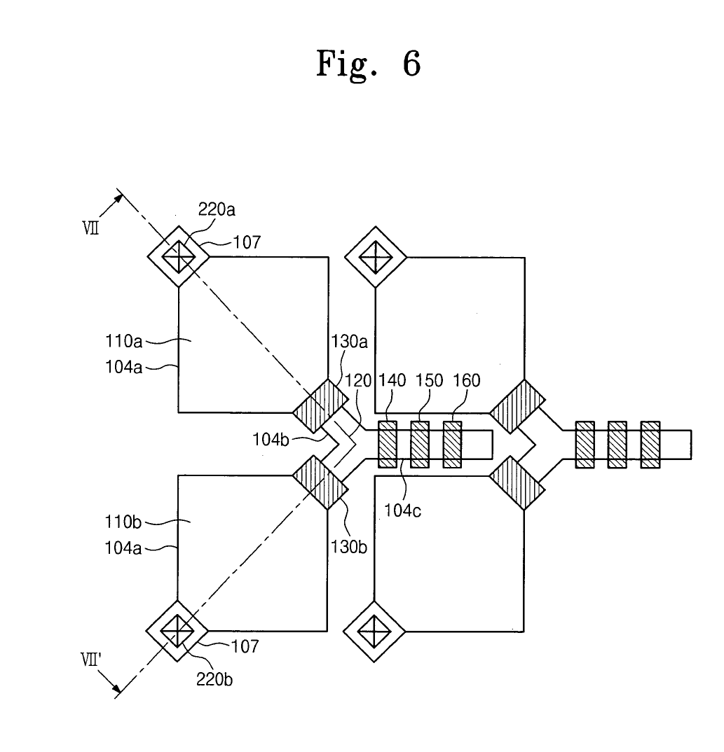

FIG. 6 is a top plan view illustrating a modified active pixel sensor (APS) array according to example embodiments. A 2-shared pixel 100′ may be formed in a one-axis-merged dual-lobe-type active region. Specifically, a 2-shared pixel may include a dual lobe active region 104a and an axis active region 104c. According to example embodiments, the dual lobe active region 104a may be symmetrically disposed in the 2-shared pixel 100′, and a connection active region 104b may be connected to the dual lobe active region 104a. The connection active region may extend to the axis active region 104c.

Photodetectors 110a and 110b may be formed at the dual lobe active region 104a, and a detecting element 120 may be formed at the connection active region 104b. According to example embodiments, one detecting element 120 may be shared with the two photodetectors 110a and 110b. Charge transfer elements 130a and 130b may be disposed on boundaries of the respective dual lobe active regions 104a and the connection active region 104b. Read elements 140, 150, and 160 connected to the detecting element 120 may be formed at the axis active region 104c.

An isolation well 107 for well driving may be disposed at the periphery of the dual lobe active region 104a. According to example embodiments, the isolation well 107 may be disposed adjacent to the respective photodetectors 110a and 110b. The isolation well 107 may be formed throughout the circumference of the respective photodetectors 110a and 110b or may be formed restrictively at a predetermined region thereof. In the latter case, the isolation well 107 may be disposed to be opposite to the detecting element 120 in consideration of a potential profile. According to example embodiments, the isolation well 107 may be disposed at a position which is adjacent to the photodetectors 110a and 110b and spaced apart from the detecting element 120.

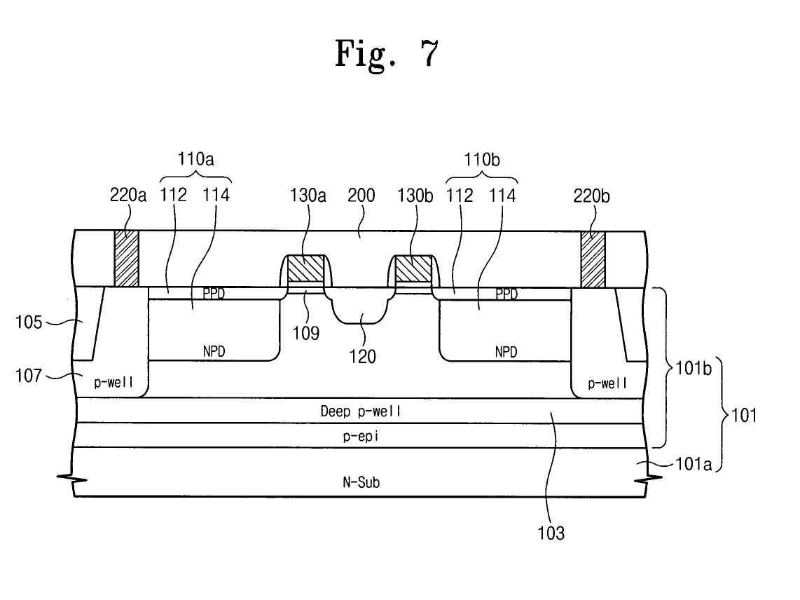

FIG. 7 is a cross-sectional view taken along the line VII-VII′ of FIG. 6, which illustrates a modified active pixel sensor (APS) array according to one embodiment of example embodiments. The numerals in FIG. 7 denote the same elements as the same numerals in FIG. 4, and duplicate explanations will be omitted.

The cross section of FIG. 7 is similar to that of the image sensor shown in FIG. 4. A detecting element 120 may be disposed between two photodetectors 110a and 110b which may be symmetrically disposed. An isolation well 107 may be disposed at the peripheral regions of the respective photodetectors 110a and 110b. The isolation well 107 may be restrictively formed at a predetermined region in the substrate 101. According to example embodiments, isolation wells 107 may be disposed at positions spaced apart from the detecting elements 120, respectively. A surface of the isolation well 107 may be partially or entirely exposed to connect the isolation well 107 to an overlying well driving contact 220.

According to example embodiments, a predetermined voltage may be applied to the respective isolation wells 107 in a 2-shared pixel 100′ according to well driving signals WD(i)a and WD(i)b. According to example embodiments, when charge transfer elements 130a and 130b in the 2-shared pixel 100′ are turned on, a negative voltage, which may be between −1.2 volts and 0 volts, may be applied to the well driving contact 220. Accordingly, excess holes in the isolation well 107 may be attracted to the well driving contact 220 to lower a potential at the isolation well 107. As a result, a potential gradient from the photodetectors 110a and 110b to the detecting element 120 may become larger when charges are transferred.

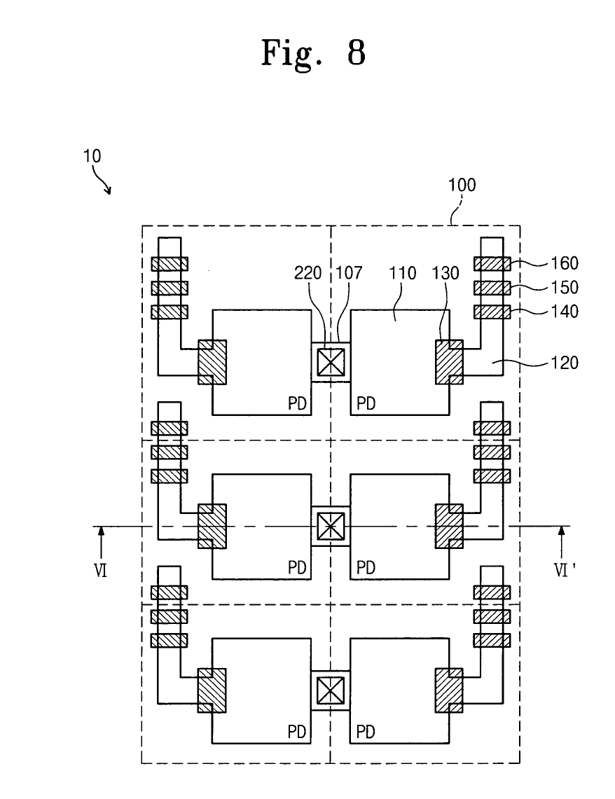

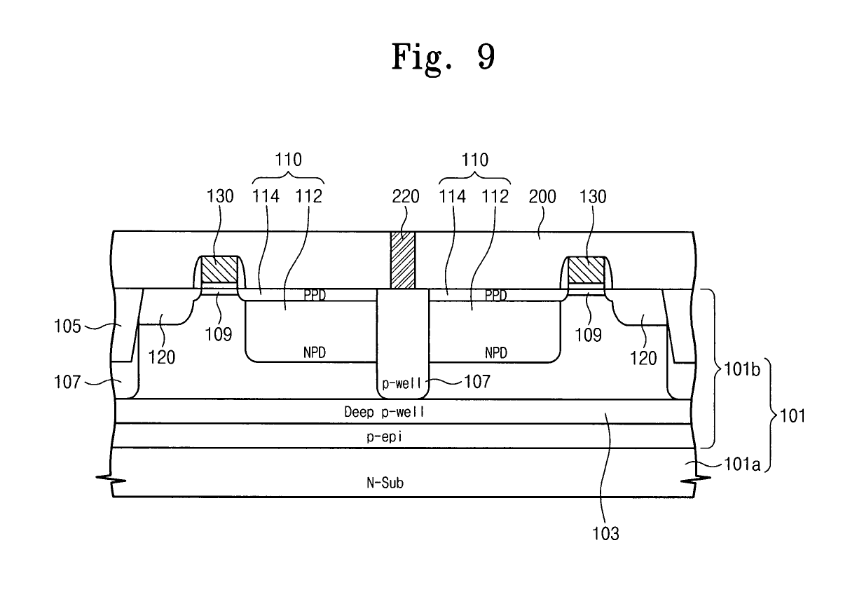

A CMOS image sensor according to example embodiments will now be described below in detail with reference to FIGS. 8 and 9. FIGS. 8 and 9 are a top plan view and a cross-sectional view, respectively, taken along the line IX-IX′ of FIG. 8, which illustrate the CMOS image sensor according to example embodiments. Numerals in FIGS. 8 and 9 denote the same elements as the same numerals in FIGS. 3 and 4, and duplicate explanations will be omitted.

Referring to FIG. 8, an APS array region 10 may include a plurality of unit pixels 100 arranged in a matrix. A photodetector 110 may be disposed at the center of the respective unit cells. A detecting element 120, a charge transfer element 130, a reset element 140, an amplifier 150, and a selector 160 may be disposed at the periphery of the photodetector 110. In the unit pixel 100, an isolation well 107 for well driving may be formed at a position that is adjacent to the photodetector 110 and spaced apart from the detecting element 120. The unit pixels 100 may be disposed to allow photodetectors 110 to be disposed adjacent to each other so that the unit pixels may share the isolation well 107 for well driving. According to example embodiments, an isolation well 107 may be disposed between a plurality of photodetectors 110 in the APS region 10. As set forth above, the isolation well 107 for well driving may be disposed to be shared with the plurality of unit pixels, which may allow a fill factor of a CMOS image sensor to be improved.

Referring to FIG. 9, a cross section of the CMOS image sensor shown in FIG. 8 will now be described. The CMOS image sensor may use a substrate 101 including a bulk substrate 101a on which an epitaxial layer 101b may be formed. The substrate 101 may include a device isolation layer 105 disposed to define an active region of each unit pixel. An impurity region may be formed below the device isolation layer 105, and an isolation well 107 may be formed at the impurity region to suppress crosstalk between unit pixels.

The isolation well 107 may be disposed to the periphery of the photodetector 110 and doped with impurities of an opposite conductivity type to that of the photodetector 110. A surface of the isolation well 107 may be partially or entirely exposed so that a negative voltage may be applied by a well driving contact 220 when charges are transferred. The isolation well 107 may vertically extend from the surface of the substrate 101 to the deep well 103 in the substrate 101 to eject excess electrons or holes in the substrate 101.

As is described above, gates of a charge transfer element and a read element may be disposed on a substrate 101 where an active region is defined, and a photodetector 110, i.e., a pinned photodiode, may be formed on one side of a charge transfer element 130 and adjacent to an isolation well 107. According to example embodiments, an N-type impurity region 112 and a P-type impurity region 114 may be disposed adjacent to the isolation well 107, and a detecting element 120 spaced apart from the pinned photodiode 110 may be formed in the substrate 101. Additionally, a well driving contact 220 may be formed on the substrate 101, where the isolation well 107 is formed, to provide a negative voltage to the isolation well 107 during charge transfer. According to example embodiments, a heavily doped region (not shown) may be formed in a region that is in contact with the isolation well 107 and the contact 220 to decrease contact resistance.

Therefore, the well driving contact 220 providing a negative voltage during charge transfer may be shared with a plurality of unit pixels. As a result, the shared well driving contact 220 may apply a negative voltage whenever charges are transferred from respective connected unit pixels.

Although not shown in the figures, in a CMOS image sensor including 2-shared pixels according to example embodiments, an isolation well may be shared with photodetectors between adjacent two 2-shared pixels. Additionally, the isolation well may be shared between photodetectors that are symmetrically disposed in one 2-shared pixel, i.e., the isolation well may be disposed between photodiodes.

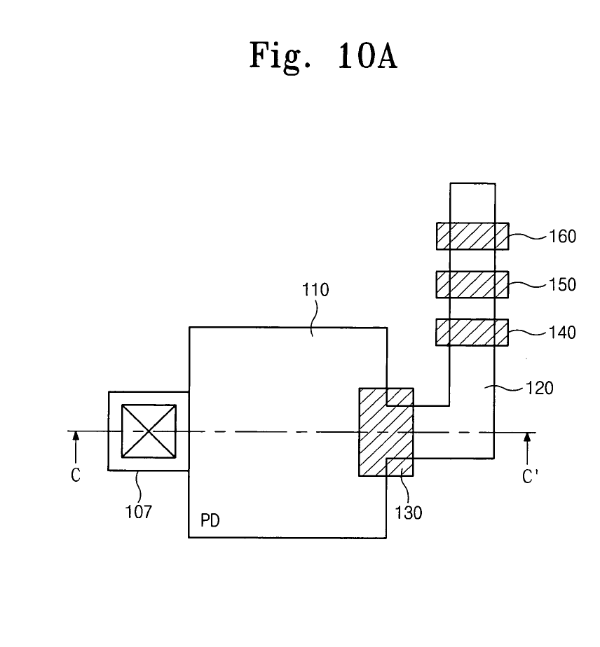

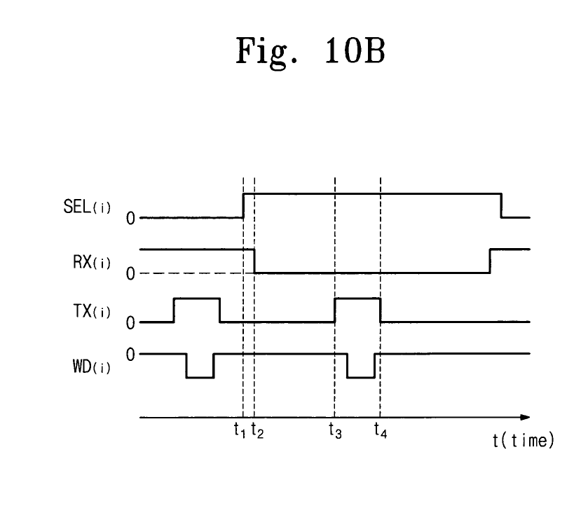

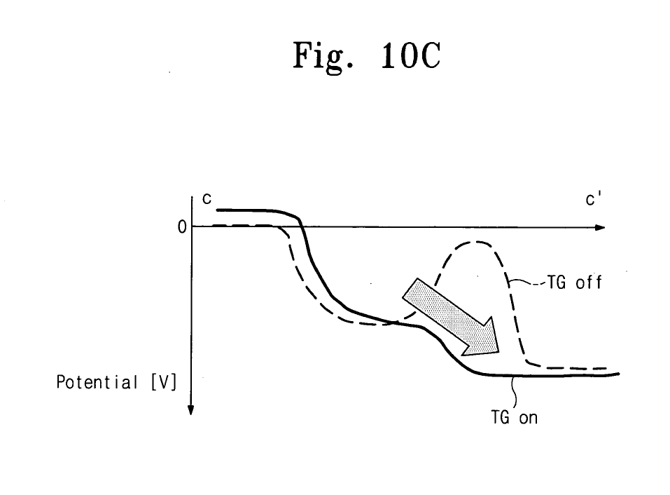

The operation of an image sensor according to example embodiments will now be described with reference to FIG. 2 and FIGS. 10A through 10C. FIG. 10A is a top plan view of a unit pixel, which illustrates the operation of a CMOS image sensor according to example embodiments. FIG. 10B is a timing diagram of the CMOS image sensor according to example embodiments. FIG. 10C is a potential diagram of the CMOS image sensor according to example embodiments, which shows potential of a section taken along the line C-C′ of FIG. 10A. In FIG. 10C, a downward direction indicates a direction in which an absolute potential increases.

All unit pixels disposed within an APS array region may commonly accumulate charges, and unit pixels disposed at a specific row may receive a characteristic reset signal RX(i), a pixel selection signal SEL(i), and a well driving signal WD(i).

Referring to FIGS. 10A through 10C, unit pixels of a specific row are unselected before t₁. Further, a pixel selection signal SEL(i) and a charge transfer signal TX(i) may be held at a low level before t₁. When the selection signal SEL(i) goes to a high level at t₁, a selector 160 may be activated and charges stored in a detecting element 120 may be prepared to be read through an output line connected to a selected unit pixel. At this point, a reset signal RX(i) of a high level may reset the detecting element 120 by providing a power supply voltage V_{DD} to the detecting element 120. Thus, charges remaining at the detecting element 120 may all be ejected.

Afterward when the reset signal RX(i) goes to a low level at t₂, the charge transfer signal TX(i) and a well driving signal WD(i) may be held at a low level during t₂ to t₃. Therefore, potential of a photodiode, for example photodetector 110 may be high enough to accumulate photocharges in the photodetector 110. When the charge transfer signal TX(i) goes to a high level at t₃, a charge transfer element 130 may be turned on to lower potential under a transfer gate TG. Accordingly, the photocharges stored in the photodetector 110 may be transferred to the detecting element 120.

The charge transfer signal TX(i) may be held at a high level during t₃ to t₄. During this duration, the photocharges may be transferred to the detecting element 120. For a time between t₃ and t₄, a negative voltage, for example, between −1.2 and 0 volts, may be applied to an isolation well 107 adjacent to the photodetector 110 through the well driving signal WD(i). At this point, the well driving signal WD(i) may provide a negative voltage to an isolation well for the time between t₃ and t₄ and may apply a negative voltage to the isolation well 107 for a shorter time (t<t₄−t₃) within the time between t₃ and t₄. Then, providing the negative voltage to the isolation well 107 may be stopped before the charge transfer signal TX(i) goes to a low level.

According to example embodiments, potential around the photodetector 110 may become high during charge transfer duration, the time between t₃ and t₄, which may be contrary to a potential profile under a transfer gate TG. According to example embodiments, a potential gradient from the photodetector 110 to the detecting element 120 may increase while photocharges are transferred. Accordingly, the photocharges of photodetector 110 may be transferred to the detecting element 120 within a reasonable time. As a result, charge transfer efficiency and operation characteristics of an image sensor may be improved.

According to example embodiments, an isolation well may be disposed adjacent to a photodetector, and a negative voltage may be applied to the isolation well through a well driving contact. Thus, while photocharges in the photodetector are transferred to a detecting element, the negative voltage may be provided to the isolation well to increase a difference between the potential at the photodetector and the potential at the isolation well. According to example embodiments, while charges are transferred, potential at the periphery of the photodetector can be lowered to increase a potential difference between the photodetector and the detecting element. Accordingly, a potential gradient from the photodetector to the detecting element can become larger in order to transfer the photocharges to the detecting element within a reasonable time. As a result, charge transfer efficiency of a CMOS image sensor may be improved. Furthermore, operation characteristics of the CMOS image sensor may be improved.

Example embodiments having thus been described, it will be obvious that the same may be varied in many ways. Such variations are not to be regarded as a departure from the intended spirit and scope of example embodiments, and all such modifications as would be obvious to one skilled in the art are intended to be included within the scope of the following claims.

1. A CMOS image sensor comprising:
a semiconductor substrate;
at least one photodetector that is in the semiconductor substrate, the at least one photodetector being configured to accumulate photocharges;
a charge transfer element configured to control transfer of the photocharges accumulated in the at least one photodetector;
at least one detecting element configured to detect the transferred photocharges; and
at least one well driving contact configured to increase a potential difference between the at least one photodetector and the detecting element while the photocharges are transferred.

2. The CMOS image sensor as set forth in claim 1, wherein:
the semiconductor substrate further includes a well region surrounding the at least one photodetector, and the well region includes an impurity region that is adjacent to the at least one photodetector and in contact with the at least one well driving contact.

3. The CMOS image sensor as set forth in claim 2, wherein
the well region has a different conductivity type than the at least one photodetector.

4. The CMOS image sensor as set forth in claim 2, wherein
the at least one well driving contact is configured to control a potential of the at least one photodetector by ejecting majority charge carriers of the well driving region.

5. The CMOS image sensor as set forth in claim 2, further comprising:
an impurity layer spaced apart from a surface of the semiconductor substrate and formed in the semiconductor substrate, the impurity region extending from the surface of the semiconductor substrate to a top surface of the impurity layer.

6. The CMOS image sensor as set forth in claim 2, wherein
the at least one photodetector is N-type and the well region is P-type, and
a negative voltage is applied to the at least one well driving contact while the photocharges are transferred.

7. The CMOS image sensor as set forth in claim 2, wherein
The at least one well driving contact is spaced apart from the at least one detecting element.

8. The CMOS image sensor as set forth in claim 2, wherein
the semiconductor substrate includes a plurality of photodetectors sharing one read element.

9. The CMOS image sensor of claim 1, wherein
the semiconductor substrate includes at least two pixel regions,
the at least one photodetector includes at least two photodetectors each of which is in one of the at least two pixel regions of the semiconductor substrate, each of the at least two photodetectors being configured to accumulate photocharges,
the at least one detecting element is at least two detecting elements each corresponding to one of the at least two photodetectors, and
the at least two pixel regions are adjacent to each other and share the at least one well driving contact.

10. The CMOS image sensor as set forth in claim 9, wherein
the at least two photodetectors are adjacent to each other.

11. The CMOS image sensor as set forth in claim 10, wherein
the semiconductor substrate further includes a well region surrounding the each of the adjacent photodetectors, and the well region includes an impurity region that is adjacent to each of the adjacent photodetectors and in contact with the at least one well driving contact.

12. The CMOS image sensor as set forth in claim 11, wherein
the well region has a different conductivity type than each of the adjacent photodetectors.

13. The CMOS image sensor as set forth in claim 11, wherein
the impurity region is disposed between the adjacent photodetectors.

14. The CMOS image sensor as set forth in claim 9, wherein:
the well driving contact is spaced apart from each of the at least two detecting elements.

15.-18. (canceled)

19. The CMOS image sensor of claim 1, wherein
the at least one photodetector includes two adjacent photodetectors arranged as a unit pixel, the adjacent photodetectors of the unit pixel being formed as a dual lobe structure,
the adjacent photodetectors share the at least one detecting element,
and the at least one well driving contact includes well driving contacts corresponding to each of the adjacent photodetectors, respectively.

20. The CMOS image sensor as set forth in claim 19, wherein
the semiconductor substrate further includes a well region surrounding the adjacent photodetectors, and the well region includes an impurity region that is adjacent to each of adjacent photodetectors and in contact with each of the corresponding well driving contacts.

21. The CMOS image sensor as set forth in claim 20, wherein
the well region has a different conductivity type than each of the adjacent photodetectors.

22. The CMOS image sensor as set forth in claim 20, wherein
the impurity region is disposed between the adjacent photodetectors.

23. The CMOS image sensor as set forth in claim 19, wherein
the corresponding well driving contacts are each spaced apart from the at least one detecting element.
